(19) United States
(12) Patent Application Publication
(10) Pub. No.: US 2023/0136494 A1
(43) Pub. Date: May 4, 2023

(54) VALVE SYSTEM, OUTPUT MONITORING METHOD AND OUTPUT ADJUSTING METHOD FOR DIAPHRAGM VALVE, AND SEMICONDUCTOR MANUFACTURING APPARATUS

(71) Applicant: FUJIKIN INCORPORATED, Osaka (JP)

(72) Inventors: Toshihide YOSHIDA, Osaka (JP); Tsutomu SHINOHARA, Osaka (JP); Tomohiro NAKATA, Osaka (JP); Ryutaro TANNO, Osaka (JP); Yuya SUZUKI, Osaka (JP)

(73) Assignee: FUJIKIN INCORPORATED, Osaka (JP)

(21) Appl. No.: 17/915,282

(22) PCT Filed: Mar. 1, 2021
(86) PCT No.: PCT/JP2021/007694

§ 371 Date: Sep. 28, 2022

(30) Foreign Application Priority Data
Mar. 30, 2020 (JP) 2020-059705

(51) Int. Cl. F16K 37/00; F16K 7/16; H01L 21/67; C23C 16/455

(52) U.S. Cl. CPC F16K 37/005; F16K 7/16; F16K 37/0041; H01L 21/67253; H01L 21/67069; C23C 16/45544

(57) ABSTRACT

[Problem] To provide a valve system capable of monitoring in real time a mass of gas supplied from a valve that is periodically opened and closed, and that is capable of adjusting the output mass of gas supplied from the valve to be close to a target mass.

[Solution] The valve system operates a main actuator 60 to make a diaphragm periodically open and close a flow path (step S2), calculate an output mass of fluid that passes through the a between the diaphragm and a valve seat and output from the diaphragm valve based on displacement data detected by a displacement sensor (step S3), determines an adjustment lift amount based on the calculated output mass, and adjusts a lift amount Lf of the diaphragm 20 by the determined adjustment lift amount (step S4).

### TECHNICAL FIELD

The present invention relates to a valve system, an output monitoring method and an output adjusting method for diaphragm valve, and a semiconductor manufacturing apparatus using the valve system.

### BACKGROUND ART

In a process of depositing a film on a substrate by atomic layer deposition (ALD) method or a process of etching by atomic layer etching (ALE) method, in order to stably supply a process gas, the process gas supplied from a fluid control device is temporarily stored in a tank as a buffer, and a diaphragm valve provided in the immediate vicinity of the processing chamber is frequently opened and closed to supply the process gas from the tank to a processing chamber in a vacuum atmosphere. As such a diaphragm valve provided in the immediate vicinity of the processing chamber, see for example, Patent Literature 1.

In the semiconductor manufacturing process by ALD method or ALE method, it is necessary to precisely adjust the mass of the process gas.

### PATENT LITERATURE

PTL 1: Japanese Laid-Open Patent Application No. 2007-64333

### SUMMARY OF INVENTION

### Technical Problem

However, in the prior art, it was impossible to monitor in real time the mass of the gas supplied from the diaphragm valve which is opened and closed periodically.

It was also difficult to control the output mass of the gases supplied from several diaphragm valves equally due to difference between the diaphragm valves in mechanical characteristic and flow path resistance etc.

One of the objects of the present invention is to provide a valve system capable of monitoring in real time the output mass of the gas supplied from a valve which is opened and closed periodically.

Another object of the present invention is to provide a valve system capable of adjusting the output mass of gas supplied from a valve, which is opened and closed periodically, toward a target mass.

Still another object of the present invention is to provide a semiconductor manufacturing apparatus using the above-described valve system.

### Solution to Problem

The valve system according to the present invention comprises: a diaphragm valve including a body defining a flow path through which fluid flows, a diaphragm defining a portion of the flow path and opening and closing flow path by contacting to and separating from a valve seat provided in the body, an operating member for operating the diaphragm, the operating member movably provided between a closed position for making the diaphragm close the flow path and an open position for making the diaphragm open the flow path, and a drive mechanism for moving the operating member to the open or closed position;

a displacement sensor for detecting a displacement of the operating member with respect to the body;

a drive control unit for operating the drive mechanism to make the diaphragm periodically open and close the flow path;

an output monitor unit that calculates an output mass of a fluid that passes through a gap between the diaphragm and the valve seat and is output from the diaphragm valve using the detected displacement data of the displacement sensor.

Preferably, a configuration may be adopted in which the output monitor unit calculates the output mass based on a time integration of the displacement data detected by the displacement sensor.

The valve system of the present invention further comprises a lift amount adjustment mechanism for adjusting the lift amount of the diaphragm defined by the operating member positioned in the open position.

Preferably, a configuration may be adopted in which the valve system of the present invention further comprises an output adjustment unit that determines the adjustment lift amount based on the output mass calculated by the output monitor unit, and makes the lift amount adjustment mechanism adjust the lift amount with the determined adjustment lift amount to adjust the output mass of the fluid output from the diaphragm valve.

An output monitoring method of a diaphragm valve of the present invention is a method for monitoring an output of a diaphragm valve comprising: a body defining a flow path through which a fluid flows; a diaphragm defining a portion of the flow path and opening and closing the flow path by contacting to and separating from a valve seat provided in the body; an operating member for operating the diaphragm, the operating member movably provided between a closed position for making the diaphragm close the flow path and an open position for making the diaphragm open the flow path; and a drive mechanism for moving the operating member to the open or closed position,

the method comprising: supplying a pressure-controlled fluid to the diaphragm valve;

operating the driving mechanism to make the diaphragm periodically open and close the flow path;

detecting a displacement of the operating member with respect to the body; and

using the detected displacement data, calculating the output mass of the fluid that passes through a gap between the diaphragm and the valve seat and is output from the diaphragm valve.

An output adjusting method of a diaphragm valve of the present invention is a method for adjusting an output of a diaphragm valve comprising: a body defining a flow path through which a fluid flows; a diaphragm defining a portion of the flow path and opening and closing the flow path by contacting to and separating from a valve seat provided in the body; an operating member for operating the diaphragm, the operating member movably provided between a closed position for making the diaphragm close the flow path and an open position for making the diaphragm open the flow path; a drive mechanism for moving the operating member to the open or closed position; and a lift amount adjustment mechanism for adjusting a lift amount of the diaphragm valve defined by the operating member positioned at the open position,

the method comprising: supplying a pressure-controlled fluid to the diaphragm valve;

operating the driving mechanism to make the diaphragm periodically open and close the flow path;

detecting a displacement of the operating member with respect to the body;

using the detected displacement data, calculating an output mass of the fluid that passes through a gap between the diaphragm and the valve seat and is output from the diaphragm valve; and

determining an adjustment lift amount based on the calculated output mass and adjusting a lift amount by the lift amount adjustment mechanism with the determined adjustment lift amount.

A semiconductor manufacturing apparatus of the present invention is a semiconductor manufacturing apparatus comprising the above-described valve system for controlling a supply of a process gas in a manufacturing process of a semiconductor device requiring a processing step with the process gas in a sealed chamber.

### Advantageous Effects of Invention

According to the present invention, it is possible to monitor in real time the mass of a gas supplied from the valve which is periodically opened and closed.

Further, according to the present invention, it is possible to precisely adjust an output mass of a fluid supplied every time the valve is opened and closed.

### BRIEF DESCRIPTION OF DRAWINGS

FIG. 1A is a longitudinal sectional view of a diaphragm valve, and is a sectional view taken along a line 1a-1a in FIG. 1B.

FIG. 1B is a top view of the diaphragm valve in FIG. 1A.

FIG. 1C is an enlarged cross-sectional view of an actuator portion of the diaphragm valve in FIG. 1A.

FIG. 1D is an enlarged cross-sectional view of the actuator portion along a 1D-1D line in FIG. 1B.

FIG. 1E is an enlarged cross-sectional view in a circle A in FIG. 1A.

FIG. 2 is an explanatory diagram showing the operation of the piezoelectric actuator.

FIG. 3 is an enlarged cross-sectional view of a main portion for explaining a fully closed state of the diaphragm valve in FIG. 1A.

FIG. 4 is an enlarged cross-sectional view of a main portion for explaining the fully open state of the diaphragm valve in FIG. 1A.

FIG. 5 is an enlarged cross-sectional view of a main portion for explaining the state when adjusting the flow rate (when the flow rate is reduced) of the valve device in FIG. 1A.

FIG. 6 is an enlarged cross-sectional view of a main portion for explaining a state when adjusting the flow rate (when the flow rate is increased) of the valve device in FIG. 1A.

FIG. 7 is a schematic diagram which shows a valve system according to an embodiment of the present invention, and an application example to a process gas control system of a semiconductor manufacturing apparatus.

FIG. 8 is a graph which shows an example of a temporal displacement data V of an operating member, an output (flow rate) Q from a diaphragm valve, and a pressure value when the diaphragm valve is opened and closed periodically.

FIG. 9A is a flowchart showing an example of processing in a controller.

FIG. 9B is a flowchart showing an example of drive control process.

FIG. 9C is a flowchart showing an example of output monitor process.

FIG. 9D is a flowchart showing an example of output adjustment process.

FIG. 9E is a flowchart showing another example of the output adjustment process.

### DESCRIPTION OF EMBODIMENTS

### Diaphragm Valve

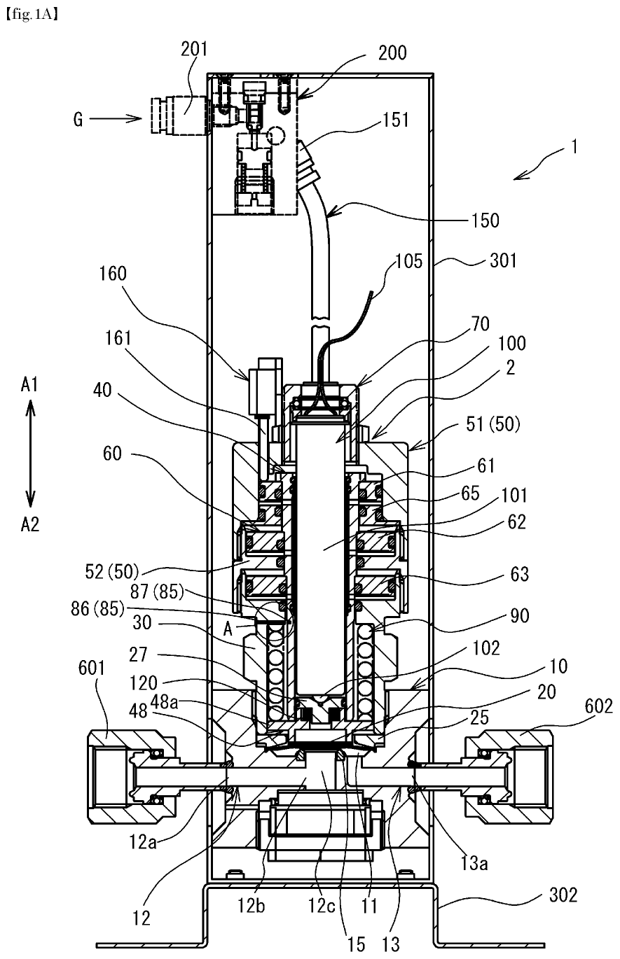

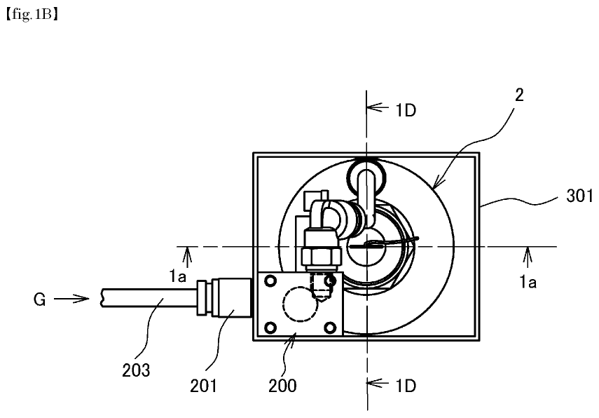

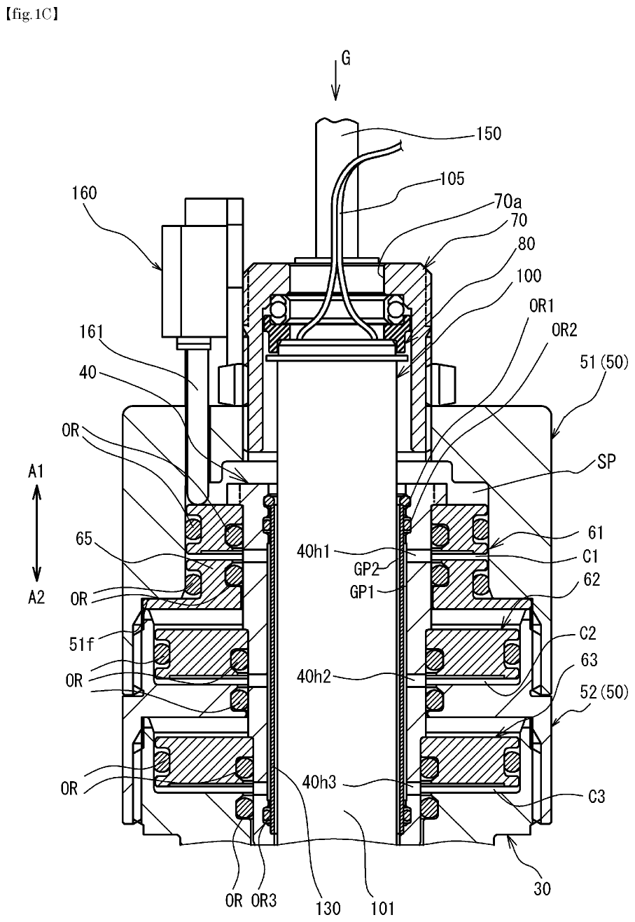

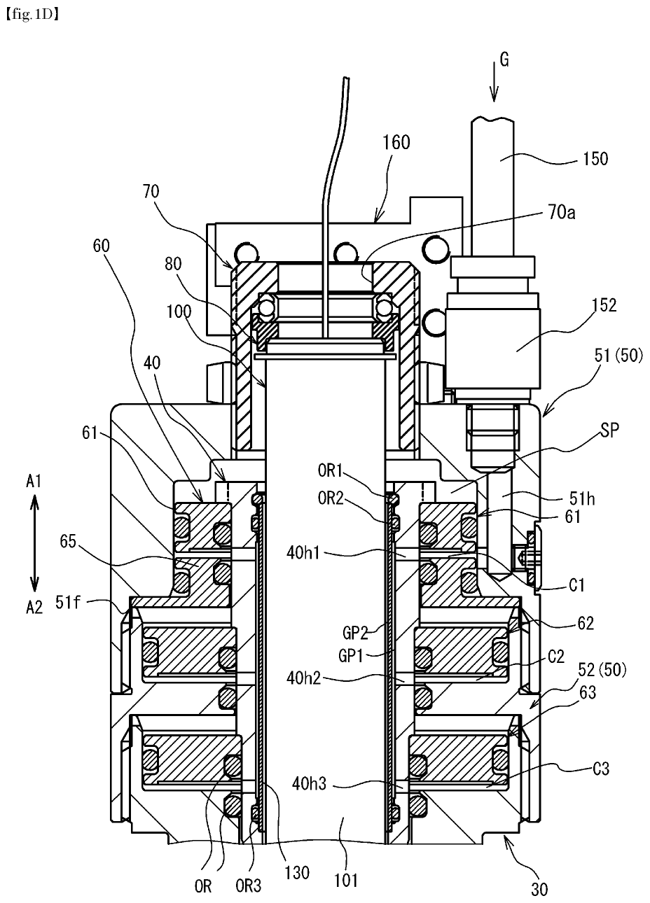

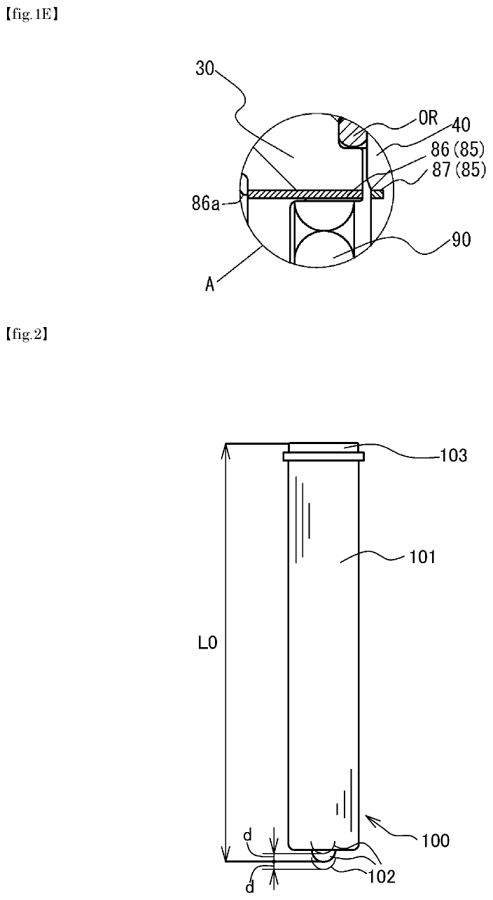

FIG. 1A is a cross-sectional view showing the configuration of a diaphragm valve 1, showing a state in which the valve is fully closed. FIG. 1B is a top view of the diaphragm valve 1, FIG. 1C is an enlarged longitudinal sectional view of an actuator portion of the diaphragm valve 1, FIG. 1D is an enlarged longitudinal sectional view of the actuator portion in a direction 90 degrees different from that of FIG. 1C, and FIG. 1E is an enlarged sectional view in a circle A in FIG. 1A. In the following explanations, A1 in FIG. 1A indicates the upward direction, and A2 indicates the downward direction.

The diaphragm valve 1 comprises a housing box 301 provided on a support plate 302, a valve body 2 installed in the housing box 301, and a pressure regulator 200 installed in a ceiling portion of the housing box 301.

In FIGS. 1A to 1E, 10 indicates a body, 15 indicates a valve sheet, 20 indicates a diaphragm, 25 indicates a presser adapter, 27 indicates an actuator receiver, 30 indicates a bonnet, 40 indicates an operating member, 48 indicates a diaphragm presser, 50 indicates a casing, 60 indicates a main actuator as a driving mechanism, 70 indicates an adjustment body, 80 indicates an actuator presser, 85 indicates a displacement sensor, 86 indicates a magnetic sensor, 87 indicates a magnet, 90 indicates a coil spring, 100 indicates a piezoelectric actuator as a lift amount adjusting mechanism, 120 indicates a disc spring, 130 indicates a partition wall member, 150 indicates a supply pipe, 160 indicates a limit switch, OR indicates an O-ring as a seal member, and G indicates a compressed air.

The body 10 is made of a metal such as stainless steel and defines flow paths 12, 13. The flow path 12 has one end that opens on one side surface of the body 10 as an opening 12a, and a pipe joint 601 is connected to the opening 12a by welding. The other end 12b of the flow path 12 is connected to a flow path 12c extending in the vertical directions A1 and A2 of the body 10. The upper end portion of the flow path 12c is opened at an upper surface side of the body 10, the upper end portion is opened at a bottom surface of a recess 11 formed on the upper surface side of the valve body 10, and the lower end portion is opened at the lower surface side of the body 10.

The valve seat 15 is provided around the opening of the upper end portion of the flow path 12c. The valve seat 15 is made of synthetic resin (PFA, PA, PI, PCTFE, etc.), it is fitted and fixed to a mounting groove provided in the opening periphery of the upper end side of the flow path 12c. In the present embodiment, the valve seat 15 is fixed in the mounting groove by caulking.

The flow path 13 has one end that opens at the bottom surface of the recess 11 of the valve body 10 and the other end that opens as an opening 13a on a side surface of the body 10 on the opposite side of the flow path 12, and a pipe joint 602 is connected to the opening 13a by welding.

The diaphragm 20 is disposed above the valve seat 15, defines a flow path communicating the flow path 12c and the flow path 13, and opens and closes the gateway between the flow paths 12 and 13 by moving the central portion thereof up and down to contact to and separate from the valve seat 15. In the present embodiment, the diaphragm 20 has a spherical shell shape that is an upward convex arc shape in natural state formed by swelling upward a central portion of a metal thin plate of special stainless steel or the like and a nickel-cobalt alloy thin plate. Three such special stainless steel thin plates and one nickel-cobalt alloy thin plate are laminated to form a diaphragm 20.

The diaphragm 20 has an outer peripheral edge portion mounted on a protruding portion formed on the bottom of a recess 11 of the body 10, and by inserting the lower end portion of the bonnet 30 into the recess 11 and screwing the lower end portion with the screw portion of the body 10, the diaphragm is pressed toward the protruding portion of the body 10 via a presser adapter 25 made of stainless alloy and is clamped and fixed in an airtight state. The nickel-cobalt alloy thin film can be used in other configurations as the diaphragm which is arranged on the gas contact side.

The operating member 40 is a member for operating the diaphragm 20 so that the diaphragm 20 opens and closes the gateway between the flow path 12 and the flow path 13, and is formed in a substantially cylindrical shape, opened at its upper end side. The operating member 40 is fitted to the inner peripheral surface of the bonnet 30 via an O-ring OR (see FIGS. 1C and 1D) and is supported movably in the vertical directions A1 and A2.

On the lower end surface of the operating member 40A, a diaphragm presser 48 made of a synthetic resin such as polyimide is mounted and abutted on the upper surface of the central portion of the diaphragm 20.

A coil spring 90 is provided between the upper surface of a flange portion 48a formed on the outer peripheral portion of the diaphragm presser 48 and the ceiling surface of the bonnet 30, and the operating member 40 is constantly biased downward A2 by the coil spring 90. Therefore, when the main actuator 60 is not operated, the diaphragm 20 is pressed against the valve seat 15, and the gateway between the flow path 12 and the flow path 13 is closed.

Between the lower surface of the actuator receiver 27 and the upper surface of the diaphragm presser 48, a disc spring 120 is provided as an elastic member.

The casing 50 is composed of an upper casing member 51 and a lower casing member 52, and a screw on the inner circumference of the lower end portion of the lower casing member 52 is screwed into a screw on the outer circumference of the upper end portion of the bonnet 30. Further, a screw on the inner circumference of the lower end portion of the upper casing member 51 is screwed into a screw on the outer circumference of the upper end portion of the lower casing member 52.

An annular bulkhead 65 is fixed between the upper end portion of the lower casing member 52 and an opposing surface 51f of the upper casing member 51 facing the upper end portion of the lower casing member 52. Between the inner peripheral surface of the bulkhead 65 and the outer peripheral surface of the operating member 40 and between the outer peripheral surface of the bulkhead 65 and the inner peripheral surface of the upper casing member 51, sealing is provided by respective O-rings OR.

The main actuator 60 has annular first to third pistons 61, 62, 63. The first to third pistons 61, 62, and 63 are fitted to the outer peripheral surface of the operating member 40 and are movable in the vertical directions A1 and A2 together with the operating member 40. Sealing is provided by a plurality of O-rings OR between the inner peripheral surfaces of the first to third pistons 61, 62, 63 and the outer peripheral surface of the operating member 40, and between the outer peripheral surfaces of the first to third pistons 61, 62, 63 and the inner peripheral surfaces of the upper casing member 51, the lower casing member 52, and the bonnet 30.

As shown in FIGS. 1C and 1D, a cylindrical partition wall member 130 is fixed to the inner peripheral surface of the operating member 40 so as to have a gap GP1 between the inner peripheral surface of the operating member 40. The gap GP1 is sealed by a plurality of O-rings OR1˜OR3 provided between the outer peripheral surface of the upper end side and the lower end side of the partition wall member 130 and the inner peripheral surface of the operating member 40, and forms a flow path of a compressed air G as a driving fluid. The flow path formed by the gap GP1 is concentrically arranged with the piezoelectric actuator 100. A gap GP2 is formed between a casing 101 of the piezoelectric actuator 100 and the partition wall member 130, which will be described later.

As shown in FIG. 1D, pressure chambers C1 to C3 are formed under the lower surfaces of the first to third pistons 61, 62, and 63, respectively.

Flow passages 40h1, 40h2, 40h3 are formed to penetrate radially through the operating member 40 at positions communicating with the pressure chambers C1, C2, and C3. The flow passages 40h1, 40h2, 40h3 are each a plurality of flow passages formed at equal intervals in the circumferential direction of the operating member 40. The flow passages 40h1, 40h2, 40h3 are each connected to the flow passage formed by the gap GP1.

The upper casing member 51 of the casing 50 is formed with a flow passage 51h which opens at the upper surface and extends in the vertical directions A1 and A2 and communicates with the pressure chamber C1. A supply pipe 150 is connected to the opening of the flow passage 51h via a pipe joint 152. As a result, the compressed air G supplied from the supply pipe 150 is supplied to the pressure chambers C1, C2, and C3 through the flow passages described above.

Space SP above the first piston 61 in the casing 50 is connected to the atmosphere through a through hole 70a of the adjustment body 70.

As shown in FIG. 1C, the limit switch 160 is installed on the casing 50, and a movable pin 161 penetrates the casing 50 and is in contact with the upper surface of the first piston 61. The limit switch 160 detects the amount of movement of the first piston 61 (operating member 40) in the vertical directions A1, A2 in response to the movement of the movable pin 161.

### Displacement Sensor

As shown in FIG. 1E, the displacement sensor 85 is provided on the bonnet 30 and the operating member 40 and includes a magnetic sensor 86 embedded along the radial direction of the bonnet 30 and a magnet 87 embedded in a portion of the circumferential direction of the operating member 40 so as to face the magnetic sensor 86.

In the magnetic sensor 86, a wiring 86a is led out to the outside of the bonnet 30, the wiring 86a is composed of a feeder line and a signal line, and the signal line is electrically connected to a controller 410 to be described later. Examples of the magnetic sensor 86 include those utilizing a Hall element, those utilizing a coil, those utilizing an AMR element whose resistance value changes depending on the strength and orientation of the magnetic field, or the like, and position detection can be made in non-contact manner by combining with the magnet.

The magnets 87 may be magnetized in the vertical directions A1 and A2, or may be magnetized in the radial direction. Further, the magnet 87 may be formed in a ring shape.

In the present embodiment, the magnetic sensor 86 is provided on the bonnet 30 and the magnet 87 is provided on the operating member 40, but it is not limited thereto, and can be changed as appropriate. For example, it is also possible to provide a magnetic sensor 86 on the presser adapter 25 and provide a magnet 87 at a position of a flange portion 48a formed on the outer peripheral portion of the diaphragm presser 48 facing thereto. It is preferable to install the magnet 87 on the side movable with respect to the body 10 and install the magnetic sensor 86 on the side not movable with respect to the valve body 10 or the body 10.

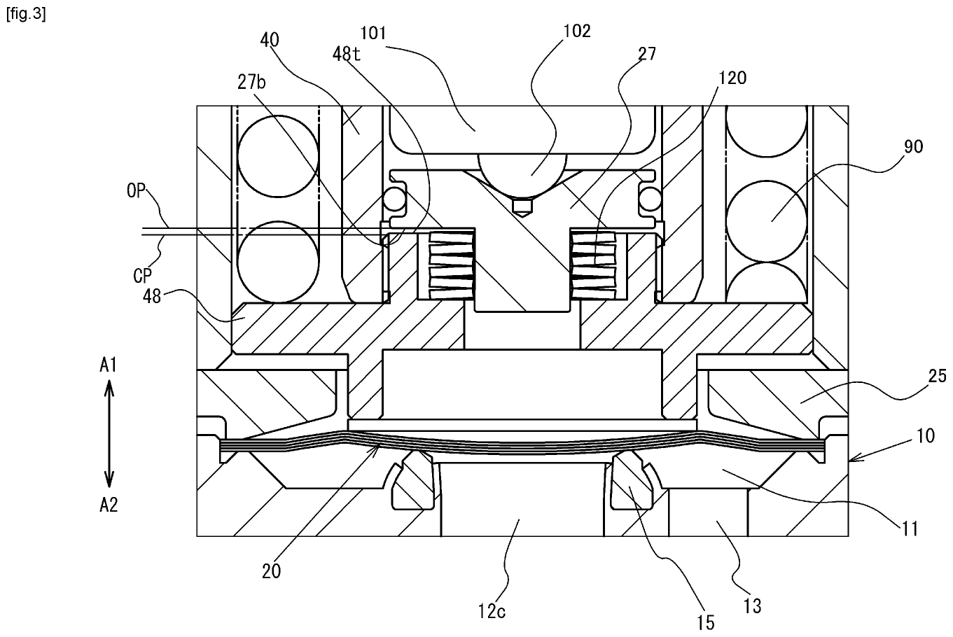

Here, the operation of the piezoelectric actuator 100 will be described with reference to FIG. 2.

The piezoelectric actuator 100 incorporates a laminated piezoelectric element (not shown) in a cylindrical casing 101 shown in FIG. 2. The casing 101 is made of a metal such as stainless steel alloy, and the end surface of the hemispherical tip end portion 102 side and the end surface of the base end portion 103 side are closed. By applying a voltage to the laminated piezoelectric element to extend it, the end surface of the casing 101 on the tip end portion 102 side is elastically deformed, and the hemispherical tip end portion 102 is displaced in the longitudinal direction. Assuming that the maximum stroke of the laminated piezoelectric element is 2d, the total length of the piezoelectric actuator 100 becomes L0 by previously applying a predetermined voltage VO at which the elongation of the piezoelectric actuator 100 becomes d. When a voltage higher than the predetermined voltage VO is applied, the total length of the piezoelectric actuator 100 becomes L0+d at the maximum, and when a voltage (including no voltage) lower than the predetermined voltage VO is applied, the total length of the piezoelectric actuator 100 becomes L0−d at the minimum. Therefore, it is possible to expand and contract the total length from tip end portion 102 to base end portion 103 in the vertical directions A1 and A2. In the present embodiment, the tip end portion 102 of the piezoelectric actuator 100 is hemispherical, but the present invention is not limited thereto, and the tip end portion may be a flat surface.

As shown in FIGS. 1A and 1C, power is supplied to the piezoelectric actuator 100 by a wiring 105. The wiring 105 is led out to an external controller 410 to be described later through the through hole 70a of the adjustment body 70.

As shown in FIGS. 1C and 1D, the vertical position of the base end portion 103 of the piezoelectric actuator 100 is defined by the lower end surface of the adjustment body 70 via the actuator presser 80. In the adjustment body 70, a screw portion provided on the outer peripheral surface of the adjustment body 70 is screwed into a screw hole formed in the upper portion of the casing 50, and by adjusting the position of the adjustment body 70 in the vertical directions A1 and A2, the position of the piezoelectric actuator 100 in the vertical directions A1 and A2 can be adjusted.

As shown in FIG. 1A, the tip end portion 102 of the piezoelectric actuator 100 is in contact with the conical receiving surface formed on the upper surface of the disk-shaped actuator receiver 27. The actuator receiver 27 is movable in the vertical directions A1 and A2.

The pressure regulator 200 has a primary side connected to a supply pipe 203 via a pipe joint 201, and a secondary side connected to a pipe joint 151 provided at the tip end portion of a supply pipe 150.

The pressure regulator 200 is a well-known poppet valve type pressure regulator, and although a detailed description thereof will be omitted, it reduces the high-pressure compressed air G supplied through the supply pipe 203 to a desired pressure to control the secondary pressure to be a preset adjusted pressure. When the pressure of the compressed air G supplied through the supply pipe 203 fluctuates due to pulsation or disturbance, this fluctuation is suppressed and output to the secondary side.

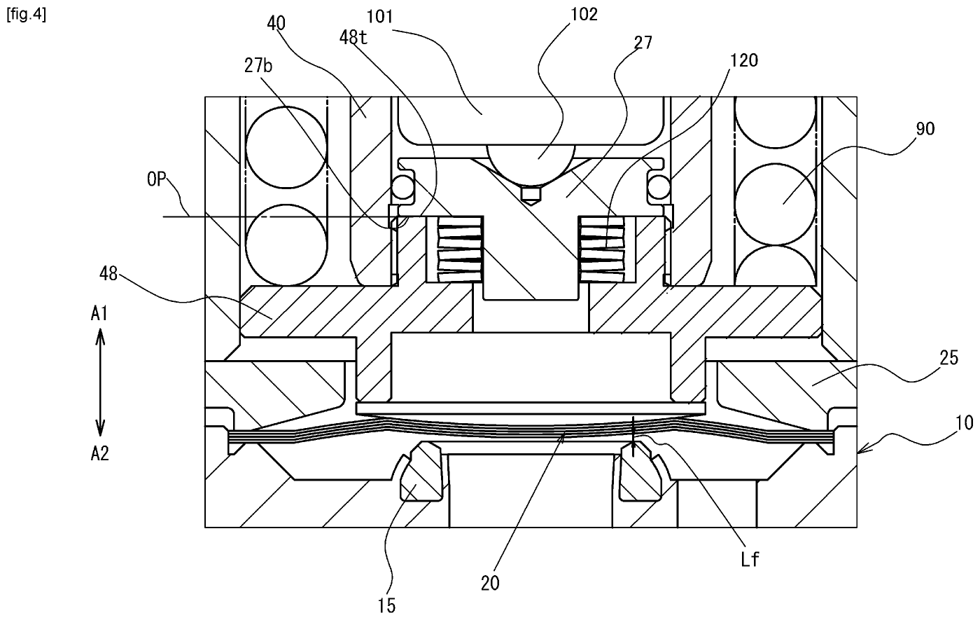

Next, the basic operation of the diaphragm valve 1 will be described referring to FIGS. 3 and 4.

FIG. 3 shows the valve fully closed state of the diaphragm valve 1. In the state shown in FIG. 3, the compressed air G is not supplied. In this state, the disc spring 120 has already been compressed to some extent and elastically deformed, and the restoring force of the disc spring 120 causes the actuator receiver 27 to be constantly biased toward the upward direction A1. Thus, the piezoelectric actuator 100 is also constantly biased toward the upward direction A1, and the upper surface of the base end portion 103 is in a state of being pressed against actuator presser 80. Thus, the piezoelectric actuator 100 receives the compressive force in the vertical directions A1 and A2 and is disposed at a predetermined position with respect to the body 10. Since the piezoelectric actuator 100 is not connected to any member, it is relatively movable in the vertical directions A1 and A2.

The number and orientation of the disc spring 120 can be appropriately changed depending on the condition. In addition to the disc spring 120, other elastic members such as a coil spring or a leaf spring can be used, but the use of a disc spring makes it easy to adjust spring stiffness, stroke, or the like.

As shown in FIG. 3, when the diaphragm 20 is in contact with the valve seat 15 and the valve is closed, a gap is formed between the regulating surface 27b on the lower surface side of the actuator receiver 27 and the contact surface 48t on the upper surface side of the diaphragm presser 48 mounted on the operating member 40. The position of the regulating surface 27b in the vertical directions A1 and A2 becomes the open position OP in a state in which the opening degree is not adjusted. The distance between the regulating surface 27b and the contact surface 48t corresponds to the lift amount Lf of the diaphragm 20. The lift amount Lf is defined by the operating member 40 positioned in the open position OP. The lift amount Lf, defines the opening degree of the valve, that is, the flow rate. The lift amount Lf can be changed by adjusting the position of the adjustment body 70 in the vertical directions A1 and A2. The Diaphragm presser 48 (operating member 40) in the state shown in FIG. 4 is located at the closed position CP with reference to the contact surface 48t. When the contact surface 48t moves to a position in contact with the regulating surface 27b of the actuator receiver 27, that is, to the open position OP, the diaphragm 20 is separated from the valve seat 15 by the lift amount Lf.

When compressed air G is supplied into the diaphragm valve 1 through the supply pipe 150, as shown in FIG. 4, a thrust force that pushes the operating member 40 upward A1 is generated in the main actuator 60. The pressure of the compressed air G is set to a value sufficient to move the operating member 40 upward A1 against the biasing force of the downward A2 acting on the operating member 40 from the coil spring 90 and disc spring 120. When such compressed air G is supplied, as shown in FIG. 4, the operating member 40 moves in the upward direction A1 while further compressing the disc spring 120, the contact surface 48t of the diaphragm presser 48 abuts the regulating surface 27b of the actuator receiver 27, and the actuator receiver 27 receives a force from the operating member 40 in the upward direction A1. This force acts as a force compressing the piezoelectric actuator 100 in the vertical directions A1 and A2 through the tip end portion 102 of the piezoelectric actuator 100. Therefore, the force in the upward direction A1 acting on the operating member 40 is received by the tip end portion 102 of the piezoelectric actuator 100, and the movement in the A1 direction of the operating member 40 is regulated in the open position OP. In this state, the diaphragm 20 is separated from the valve seat 15 by the lift amount Lf described above.

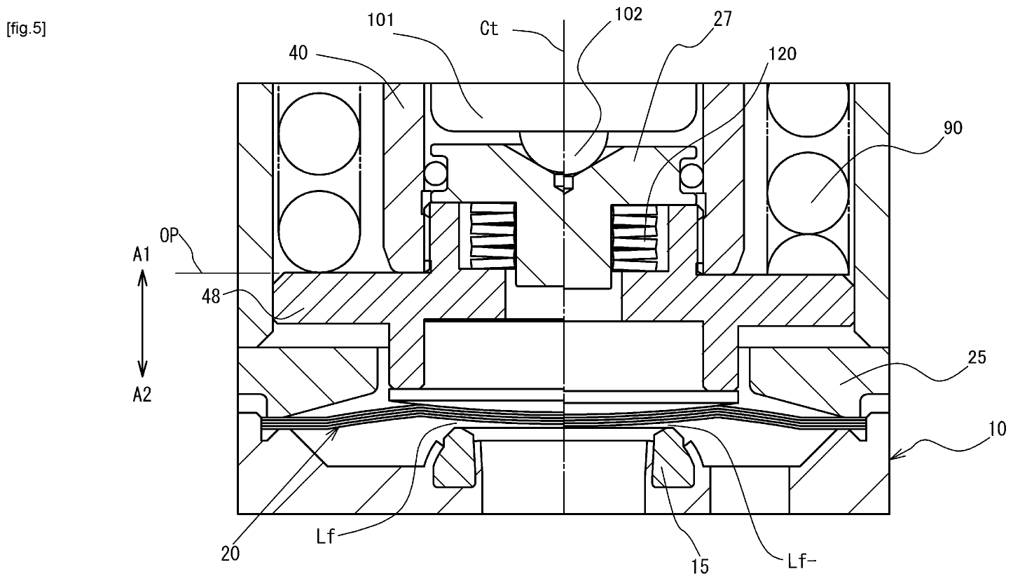

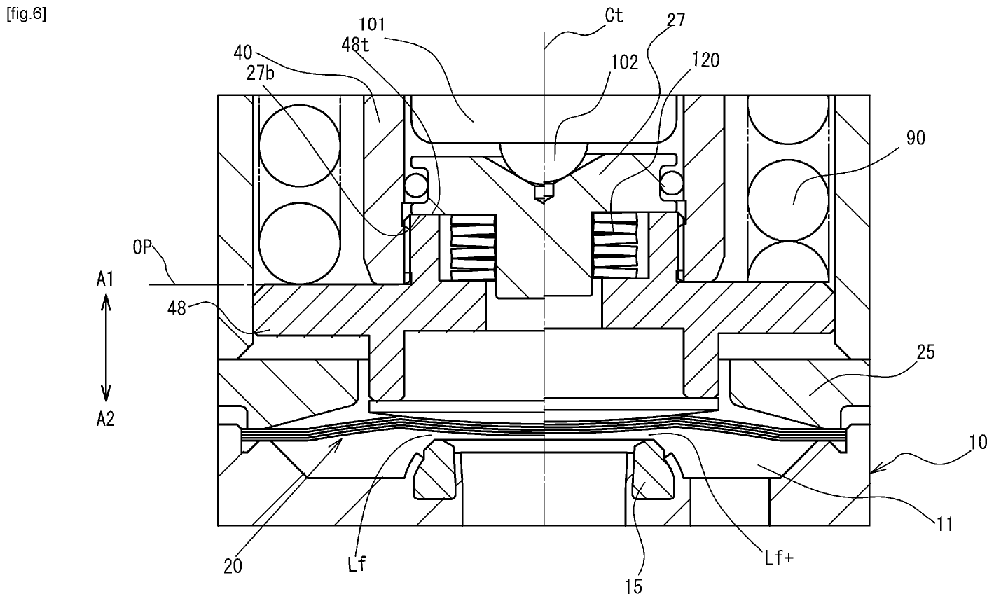

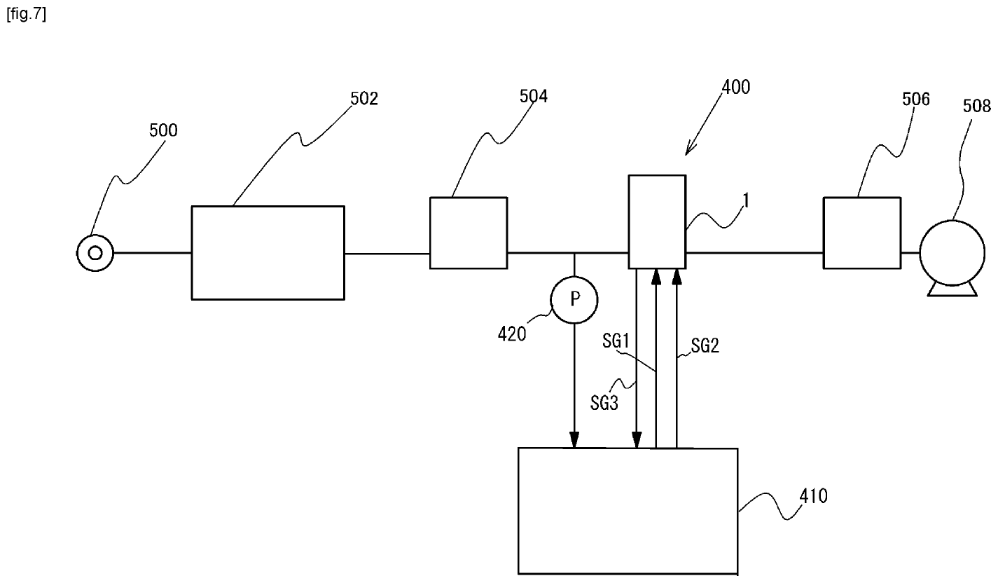

Next, an example of the flow rate adjustment of the diaphragm valve 1 will be described with reference to FIGS. 5 and 6.

First, the displacement sensor 85 described above constantly detects the relative displacement between the body 10 and the magnetic sensor 86 in the states shown in FIGS. 3 and 4. The relative positional relationship between the magnetic sensor 86 and the magnet 87 in the valve closed state shown in FIG. 3 can be set as the origin position of the displacement sensor 85. The origin position of the displacement data V to be described later is also set to this position.

Here, the left side of the center line Ct of FIGS. 5 and 6 shows a state shown in FIG. 3, the right side of the center line Ct shows a state after adjusting the position of the operating member 40 in the vertical directions A1 and A2.

When adjusting the flow rate of the fluid in the reducing direction as shown in FIG. 5, the piezoelectric actuator 100 is extended to move the operating member 40 downward A2. Thus, the lift amount Lf− after adjustment that is the distance between the diaphragm 20 and the valve seat 15 is smaller than the lift amount Lf before adjustment. The extension amount of the piezoelectric actuator 100 may be a deformation amount of the valve seat 15 detected by the displacement sensor 85.

When adjusting the flow rate of the fluid in the increasing direction, as shown in FIG. 6, the piezoelectric actuator 100 is shortened to move the operating member 40 upward A1. Thus, the lift amount Lf+ after adjustment that is the distance between the diaphragm 20 and the valve seat 15 is larger than the lift amount Lf before adjustment. The reduction amount of the piezoelectric actuator 100 may be the deformation amount of the valve seat 15 detected by the displacement sensor 85.

In the present embodiment, the maximum value of the lift amount Lf of the diaphragm 20 is about 100 to 900 μm, and the adjustment amount by the piezoelectric actuator 100 is about ±20 to 50 μm.

The stroke of the piezoelectric actuator 100 cannot cover the lift amount of the diaphragm 20, but by using the main actuator 60 operated by compressed air G and the piezoelectric actuator 100 together, it is possible to precisely adjust the flow rate with the piezoelectric actuator 100 which has a relatively short stroke, while ensuring the supply flow rate of the diaphragm valve 1 with the main actuator 60 having a relatively long stroke, and it is not necessary to manually adjust the flow rate by the adjustment body 70 or the like.

In the present embodiment, the piezoelectric actuator 100 is used as an adjustment actuator utilizing a passive element that converts a given electric power into a force that expands or contracts, but the adjustment actuator is not limited thereto. For example, an electrically driven material made of a compound that deforms in response to a change in an electric field can be used as an actuator. The shape and size of the electrically driven material can be changed by the current or voltage, and the restricted open position of the operating member 40 can be changed. Such an electrically driven material may be a piezoelectric material or an electrically driven material other than a piezoelectric material. When the material is an electrically driven material other than a piezoelectric material, the material may be electrically driven type polymeric material.

Electrically driven type polymeric material is also referred to as an electroactive polymer material (Electro Active Polymer: EAP), and includes, for example, an electric EAP driven by an external electric field or a Coulombic force, a nonionic EAP in which a solvent swelling a polymer is flown by an electric field to deform a polymer, an ionic EAP driven by movement of ions and molecules by an electric field, and any one or a combination thereof can be used.

FIG. 7 shows an exemplary valve system 400 using the diaphragm valve 1 described above and a semiconductor manufacturing apparatus in which the valve system 400 is applied to a process gas control system. This semiconductor manufacturing apparatus is used, for example, in ALD-based semiconductor manufacturing processes.

In FIG. 7, the valve system 400 includes a diaphragm valve 1 and a controller 410. The controller 410 is composed of hardware including a processor (not shown), an input/output circuit, a memory, and the like, a required software, a display, and the like. The controller 410 can output a control signal SG1 for driving and controlling the main actuator 60 and a control signal SG2 for driving and controlling the piezoelectric actuator 100 to the diaphragm valve 1, and is adapted to input a detection signal SG3 of the displacement sensor 85 provided in the diaphragm valve 1. Further, the pressure value P to be detected by a pressure sensor 420 provided in the flow path on the primary side of the diaphragm valve 1 is input to the controller 410.

In FIG. 7, 500 indicates a process gas source, 502 indicates a gas box, 504 indicates a tank, 506 indicates a processing chamber, and 508 indicates an exhaust pump.

The gas box 502 is an integrated gas system in which various fluid devices such as open-close valve, regulator, and flow rate control device are integrated and housed in a box to supply accurately weighed process gas to the processing chamber 506.

The tank 504 functions as a buffer for temporarily storing the processing gas supplied from the gas box 502, and the pressure value P of the gas supplied from the tank 504 to the diaphragm valve 1 is controlled to be constant.

The processing chamber 506 provides a sealed processing space for forming a film on a substrate by an ALD method.

An exhaust pump 508 evacuates the inside of the processing chamber 506.

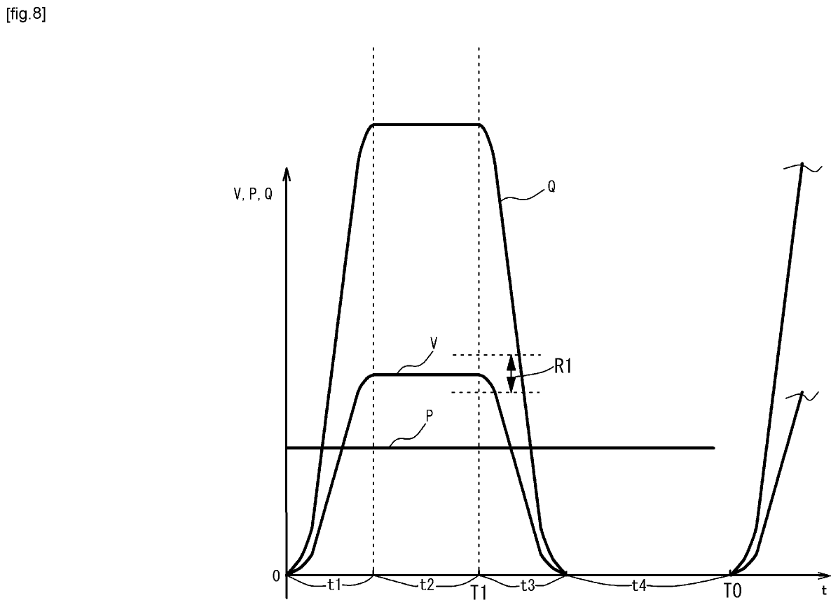

Here, an outline of the processing of the controller 410 will be described with reference to FIG. 8. Controller 410, as described later, first, periodically opens and closes the diaphragm valve 1 to supply a gas to the processing chamber 506, second, calculates and monitors the output mass of the gas output for each opening and closing of the diaphragm valve 1, and third, adjusts the lift amount Lf of the diaphragm 20 so that the output mass of the gas output for each opening and closing of the diaphragm valve 1 follows the target mass.

FIG. 8 shows the mass flow rate Q of the gas output from the diaphragm valve 1 and the displacement data V obtained from the displacement sensor 85 when the diaphragm valve 1 is periodically opened and closed, and the horizontal axis represents a time t. The mass flow rate Q is the mass of the gas per unit time output from the diaphragm valve 1. Incidentally, in FIG. 8, P indicates a pressure value, and the pressure value P is the pressure of the primary side of the diaphragm valve 1.

As shown in FIG. 8, the diaphragm valve 1 is repeatedly opened and closed at a period TO. A valve opening command is given to the diaphragm valve 1 at an initial time point 0 in the period TO, and a closing command is given to close the diaphragm valve 1 at a time point T1. In FIG. 8, t1 indicates a rising region in which the mass flow rate Q is gradually increased, t2 indicates a valve fully open region in which the mass flow rate Q is constant, t3 indicates a falling region in which the mass flow rate Q is gradually decreased, t4 indicates a valve fully closed region in which the gas output is shut off, and the period TO can be divided into each region of t1 to t4. The period TO is, for example, 2.5 seconds, and the total time of the rising region t1, the valve fully open region t2, and the falling region t3 is, for example, about 1.5 seconds.

Here, the important point is that, since the pressure value P can be regarded to be so constant that the change due to the opening and closing operation of the diaphragm valve 1 is negligible, the relationship of the following equation (1) holds between the mass flow rate Q of the gas and the pressure value P and the displacement data V.

Q=V×P (1)

If the gap between the diaphragm 20 and the valve seat 15 of the diaphragm valve 1 is regarded as a variable orifice whose cross-sectional area changes, the mass flow rate Q of the gas is proportional to the pressure value P. By utilizing the relation of equation (1), the gas outputted by the diaphragm valve 1 can be monitored in real time from the displacement data V obtained from the detected signal SG3 of the displacement sensor 85 and the pressure value P. Further, by time integrating the mass flow rate Q, it is possible to monitor the output mass of the gas output every opening and closing of the diaphragm valve 1. In the present embodiment, the pressure value P is fetched into the controller 410, but when this value is known in advance, it is not necessary to fetch the value into the controller 410. If the displacement data V, which is time series data, can be obtained, the output mass, which is the time integral of the mass flow rate Q and the mass flow rate Q of the gas, can be monitored.

In FIG. 8, the height of the flat portion of the valve fully open region t2 of the displacement data V corresponds to the lift amount Lf of the diaphragm 20. With the piezoelectric actuator 100 described above, the lift amount Lf can be adjusted up and down within the range indicated by R1. Incidentally, when the valve seat 15 is deformed by collision with the diaphragm 20, the height of the flat portion of the displacement data V gradually decreases.

If the gap between the diaphragm 20 and the valve seat 15 of the diaphragm valve 1 is regarded as a variable orifice, the relationship between the cross-sectional area of the variable orifice and the lift amount Lf is different among the plurality of diaphragm valves 1. Further, the characteristics of the rising region t1, the valve fully open region t2, and the falling region t3 are also different among the plurality of diaphragm valves 1.

Therefore, it is necessary to measure the relationship between the value of the lift amount Lf and the value of the cross-sectional area of the variable orifice with each diaphragm valve to create a data table and store the data table in the memory of the controller 410. Since the value of the cross-sectional area of the variable orifice cannot be measured directly, it is necessary to measure and acquire the relationship data between the value of the lift amount Lf and the value of the mass flow rate Q of the gas for each diaphragm valve 1 in advance.

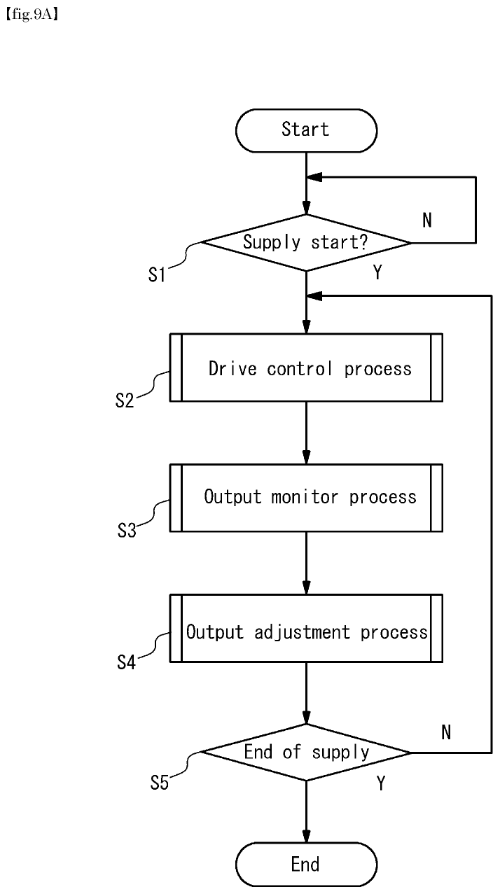

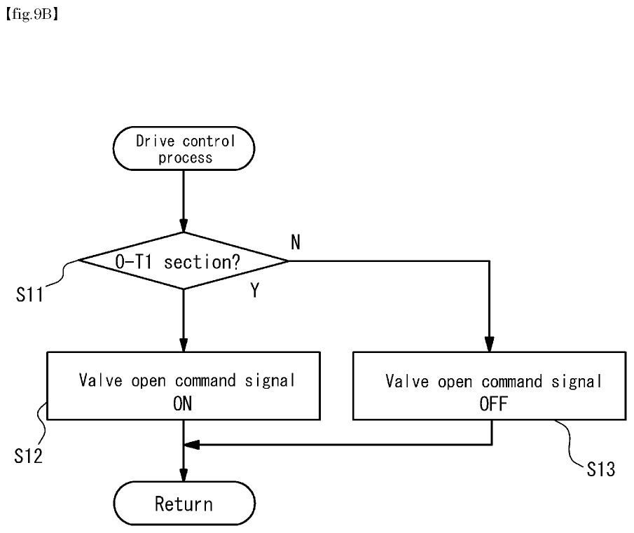

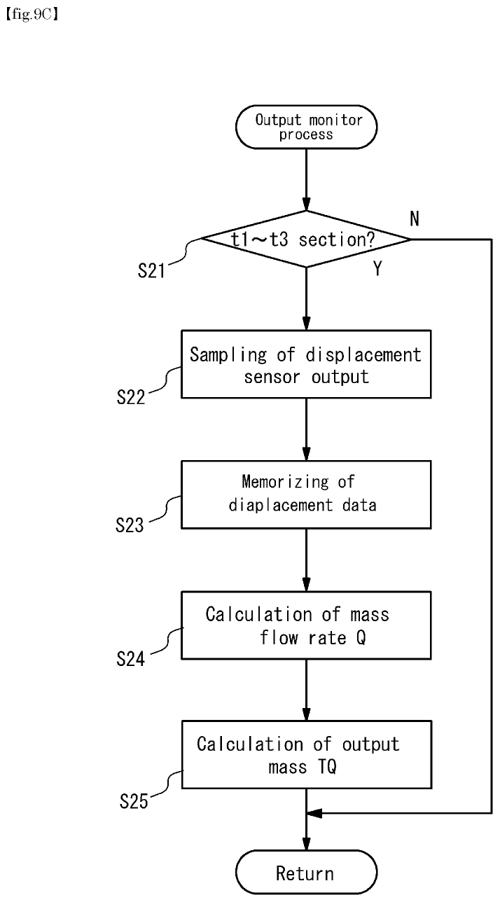

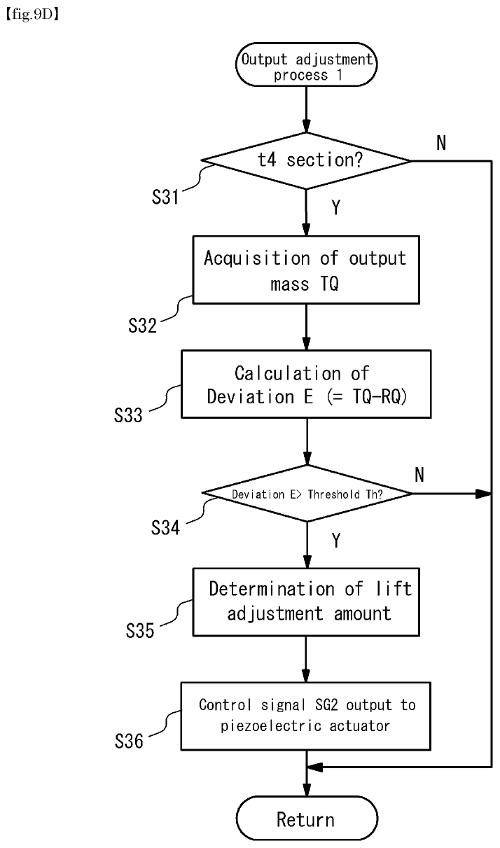

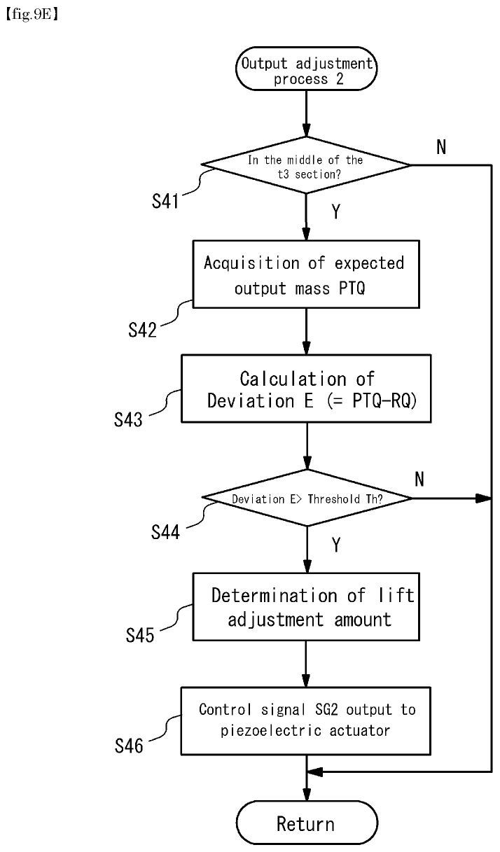

Next, an exemplary process of the controller 410 will be described with reference to the flowcharts shown in FIGS. 9A to 9D.

In the controller 410, in a case of supplying a process gas to the processing chamber 506, it is determined whether or not the supply should be started (step S1), and when it is determined that the supply should be started (step S1:Y), the drive control process of the main actuator 60 is executed (step S2). When it is determined that the supply is not to be started (step S1:N), a standby state is maintained.

In the drive control process, as shown in FIG. 9B, it is determined whether the present time is within the section from the time point 0 to the time point T1 in the period TO (step S11), and when it is determined that it is within the section (step S11:Y), the control signal SG1 output to the diaphragm valve 1 (valve opening command signal) is turned on (step S12), and when it is determined that it is outside the section (step S11:N), the control signal SG1 (valve opening command signal) is turned off (step S13). With such a process, the diaphragm valve 1 is opened and closed periodically in a period TO, and the gas is output to the gas processing chamber 506 through the diaphragm valve 1.

Next, the output monitoring process shown in FIG. 9A is performed (step S3). In the output monitoring process, as shown in FIG. 9C, it is determined whether the current time is in a section that is any of the rising region t1, the valve fully open region t2, and the falling region t3 (step S21), and when it is determined to be within the section (step S21:Y), the detected signal SG3 of the displacement sensor 85 is sampled (step S22) and stored as the displacement data V (step S23). Mass flow rate Q of the gas is calculated using the sampled displacement data V (step S24), and the mass flow rate Q is time integrated to calculate the output mass TQ of the gas (step S25). In step S21, when it is determined that the current time is outside the section described above, that is, in the valve fully closed region t4 (step S21:N), the process is terminated. Calculated mass flow Q and the output mass TQ can be graphically displayed on a display or the like.

Next, the output adjustment process 1 shown in FIG. 9A is performed (step S4).

In the output adjustment process 1, as shown in FIG. 9D, it is determined whether the current time is in the valve fully closed region t4 (step S31), and when the current time is determined to be in the valve fully closed region t4 (step S31:Y), the output mass TQ calculated in step S25 is obtained (step S32), and the deviation E between the output mass TQ and the target mass RQ is calculated (step S33). The target mass RQ is the ideal mass of the gas output in one opening and closing operation of the diaphragm valve 1. In step S31, if the current time is determined to be outside the section of the valve fully closed region t4 (step S31:N), the process is terminated.

Next, it is determined whether the deviation E is larger than the threshold value Th (step S34), and when the deviation E is determined to be larger than the threshold value Th (step S34:Y), the above-described relationship data between the above-described value of the lift amount Lf and the mass flow rate Q of the gas is referred to determine the lift adjustment amount for adjusting the lift amount Lf for canceling the deviation E (step S35). The control signal SG2 corresponding to the calculated lift adjustment amount is output to the piezoelectric actuator 100 (step S36). Thus, within the section of the valve fully closed region t4, the lift amount Lf is changed, and consequently, the mass flow rate Q when the diaphragm valve 1 is opened and closed in the next cycle is modified, and the output mass TQ follows the target mass RQ. When it is determined in step S34 that the deviation E is smaller than the threshold value Th (step S34:N), the process is terminated.

Referring back to FIG. 9A, after step S4, it is determined whether or not the supplying of the gases should be terminated (step S5), and when it is determined that the supplying of the gases should be terminated (step S5:Y), the processing is terminated, and when it is determined that the supplying of the gases should not be terminated (step S5:N), the processing of steps S2 to S4 is repeatedly executed. Note that the processes of steps S2 to S5 in FIG. 9A are executed at predetermined sampling times.

As described above, according to the present embodiment, it is possible to monitor in real time the mass flow rate Q and the output mass TQ of the gas output from the diaphragm valve 1 each time the valve is opened and closed. In addition, since the lift amount Lf can be adjusted so that the deviation E between the output mass TQ and the target mass RQ is canceled based on the output mass TQ obtained by one opening and closing operation (one cycle) of the diaphragm valve 1, the output mass of the gas supplied from the diaphragm valve 1 which is opened and closed periodically can be more precisely controlled.

In the output adjustment process 1 shown in FIG. 9D, based on the output mass TQ obtained by one opening and closing operation of the diaphragm valve 1, the lift amount Lf in the next opening and closing operation of the diaphragm valve 1 is adjusted, but the present invention is not limited thereto.

In the output adjustment process 2 shown in FIG. 9E, the adjustment lift amount is determined based on the output mass calculated during one opening and closing operation of the diaphragm valves 1, and the lift amount Lf is adjusted during the opening and closing operation of the one.

In the output adjustment process 2, as shown in FIG. 9E, it is determined whether the current time is in the falling region t3 (step S41), and when it is determined that the current time is in the falling region t3 (step S41:Y), a predicted output mass PTQ is calculated (step S42). When it is determined that the current time is not in the falling region t3 (step S41:N), the process ends.

The predicted output mass PTQ is based on, for example, the change characteristics of the mass flow rate Q (displacement data V) of the rising region t1 and the valve fully open region t2 and the falling region t3 up to the present time (that is, up to the middle of the falling region t3), and is a predicted output mass to be output when the falling region t3 is finally completed. For example, the predicted output mass PTQ output when the falling region t3 is finally completed can be calculated from the change characteristics of the output mass up to the present time and the mass flow rate Q of the falling region t3 obtained up to the present time. Incidentally, it is not limited to this method, and it is sufficient that the final output mass can be predicted by utilizing the displacement data V obtained during one opening and closing operation of the diaphragm valve 1.

Next, a deviation E between the predicted output mass PTQ and the target mass RQ is calculated (step S43). The target mass RQ is an ideal mass output in one opening and closing operation.

Then, it is determined whether or not the deviation E is larger than the threshold value Th (step S44), and if the deviation E is determined to be larger than the threshold value Th (step S44:Y), the lift adjustment amount for adjusting the lift amount Lf of the diaphragm 20 for canceling the deviation E is determined with reference to the above-described relational data between the lift amount Lf and the mass flow rate Q (step S45). The control signal SG2 corresponding to the calculated lift adjusting amount is output to the piezoelectric actuator 100 (step S46).

Thus, the lift amount Lf of the diaphragm 20 is changed within the section of the falling area t3, that is, in the middle of one opening and closing operation of the diaphragm valve 1. As a result, the mass flow rate Q and the output mass TQ is corrected in real time within the same opening and closing operation. As a result, the output mass for each opening and closing of the diaphragm valve 1 can be more precisely controlled. The lift amount Lf of the diaphragm 20 may be changed within the section of the rising region t1 and the valve fully open region t2.

If it is determined in step S44 that the deviation E is smaller than the threshold Th (step S44:N), the process is terminated.

In the above embodiment, a displacement sensor including a magnetic sensor and a magnet has been exemplified, but the displacement sensor is not limited thereto, and a non-contact type position sensor such as an optical position detection sensor can be adopted.

In the above embodiment, the piezoelectric actuator 100 is used to adjust the lift amount, but the present invention is not limited thereto, and it is also possible to adjust the lift amount Lf manually while monitoring the output of the diaphragm valve 1.

Note that the present invention is not limited to the above-described embodiment. Various additions, modifications, and the like can be made by those skilled in the art within the scope of the present invention. For example, in the above application example, the case in which the flow rate control device of the present invention is used in the semiconductor manufacturing process by the ALD method has been exemplified, but the present invention is not limited thereto, and can be applied to, for example, an atomic layer etching method or the like.

### REFERENCE SIGNS LIST

1: Diaphragm valve
2: Valve body
10: Body
11: Recess
12: Flow path
12a: Opening
12b: The other end
12c,13: Flow path
13a: Opening
15: Valve seat
20: Diaphragm
25: Presser adapter
27: Actuator receiver
27b: Regulating surface
30: Bonnet
40: Operating member
48: Diaphragm presser
48a: Flange portion
48t: Contact surface
50: Casing
51: Upper casing member
51f: Opposing surface
51h: Flow passage
52: Lower casing member
60: Main actuator
70: Adjustment body
80: Actuator presser
85: Displacement sensor
86: Magnetic sensor
86a: Wiring
87: Magnet
90: Coil spring
100: Piezoelectric actuator
101: Casing
102: Tip end portion
103: Base end portion
105: Wiring
120: Disc spring
130: Partition wall member
150: Supply pipe
151,152: Pipe joint
160: Limit switch
161: Movable pin
200: Pressure regulator
201: Pipe joint
203: Supply pipe
301: Housing box
302: Support plate
400: Valve system
410: Controller
420: Pressure sensor
502: Gas box
504: Tank
506: Processing chamber
508: Exhaust pump
601,602: Pipe joint
E: Deviation
G: Compressed air
Lf: Lift amount
OP: Open position
P: Pressure value
PTQ: Predicted output mass
Q: Mass flow rate
RQ: Target mass
TO: Period
TQ: Output mass
Th: Threshold
V: Displacement data
t1: Rising region
t2: Valve fully open region
t3: Falling region
t4: Valve fully closed region

1. A valve system comprising:
a diaphragm valve including a body defining a flow path through which a fluid flows, a diaphragm defining a portion of the flow path and opening and closing flow path by contacting to and separating from a valve seat provided in the body, an operating member for operating the diaphragm, the operating member movably provided between a closed position for making the diaphragm close the flow path and an open position for making the diaphragm open the flow path, and a drive mechanism for moving the operating member to the open or closed position;
a displacement sensor for detecting a displacement of the operating member with respect to the body,
a drive control unit for operating the drive mechanism to make the diaphragm periodically open and close the flow path;
an output monitor unit that calculates an output mass of a fluid that passes through a gap between the diaphragm and the valve seat and is output from the diaphragm valve using the detected displacement data of the displacement sensor.

2. The valve system according to claim 1, wherein the output monitor unit calculates the output mass based on a time integration of the displacement data detected by the displacement sensor.

3. The valve system according to claim 1, further comprising a lift amount adjustment mechanism for adjusting the lift amount of the diaphragm defined by the operating member positioned in the open position.

4. The valve system according to claim 3, wherein the lift amount adjustment mechanism includes an actuator using a passive element that expands and contracts in response to an external input signal.

5. The valve system according to claim 3, further comprising an output adjustment unit that determines the adjustment lift amount based on the output mass calculated by the output monitor unit, and makes the lift amount adjustment mechanism adjust the lift amount by the determined adjustment lift amount to adjust the output mass of the fluid output from the diaphragm valve.

6. The valve system according to claim 5, wherein the output adjustment unit compares the calculated output mass by one opening and closing operation of the diaphragm valve with the target mass, determines the adjustment lift amount based on the deviation between the two, and makes the lift amount adjustment mechanism adjust the lift amount by the adjusted lift amount.

7. The valve system according to claim 5, wherein the output adjustment unit determines the adjustment lift amount based on the output mass calculated in the middle of one opening and closing operation of the diaphragm valve and makes the lift amount adjustment mechanism adjust the lift amount in the middle of one opening and closing operation.

8. An output monitoring method for monitoring the output of a diaphragm valve comprising: a body defining a flow path through which fluid flows; a diaphragm defining a portion of the flow path and opening and closing the flow path by contacting to and separating from a valve seat provided in the body; an operating member for operating the diaphragm, the operating member movably provided between a closed position for making the diaphragm close the flow path and an open position for making the diaphragm open the flow path; and a drive mechanism for moving the operating member to the open or closed position,
the method comprising:
supplying a pressure-controlled fluid to the diaphragm valve;
operating the drive mechanism to make the diaphragm periodically open and close the flow path;
detecting a displacement of the operating member with respect to the body; and
using the detected displacement data of the operating member, calculating the output mass of the fluid that passes through a gap between the diaphragm and the valve seat and is output from the diaphragm valve.

9. An output adjusting method for adjusting an output of a diaphragm valve comprising: a body defining a flow path through which a fluid flows; a diaphragm defining a portion of the flow path and opening and closing the flow path by contacting to and separating from a valve seat provided in the body; an operating member for operating the diaphragm, the operating member movably provided between a closed position for making the diaphragm close the flow path and an open position for making the diaphragm open the flow path; a drive mechanism for moving the operating member to the open or closed position; and a lift amount adjustment mechanism for adjusting a lift amount of the diaphragm valve defined by the operating member positioned at the open position,
the method comprising:
supplying a pressure-controlled fluid to the diaphragm valve;
operating the driving mechanism to make the diaphragm periodically open and close the flow path;
detecting a displacement of the operating member with respect to the body;
using the detected displacement data, calculating an output mass of the fluid that passes through the gap between the diaphragm and the valve seat and is output from the diaphragm valve; and
determining an adjustment lift amount based on the calculated output mass, and
adjusting a lift amount by the lift amount adjustment mechanism with the determined adjusted lift amount.

10. (canceled)
